(19) United States
(12) Patent Application Publication
(10) Pub. No.: US 2026/0334153 A1
(43) Pub. Date: Oct. 22, 2026

(54) ELECTROSTATIC MASK CHUCK AND DEPOSITION APPARATUS INCLUDING THE SAME

(71) Applicant: Samsung Display Co., Ltd., Yongin-si (KR)

(72) Inventor: Jinyong LEE, Yongin-si (KR)

(73) Assignee: Samsung Display Co., Ltd., Yongin-si (KR)

(21) Appl. No.: 19/447,832

(22) Filed: Jan. 13, 2026

(30) Foreign Application Priority Data
Apr. 21, 2025 (KR) 10-2025-0051389

(51) Int. Cl. H10P 72/72; C23C 14/04; C23C 14/24

(52) U.S. Cl. CPC H10P 72/722; C23C 14/042; C23C 14/24

(57) ABSTRACT

An electrostatic mask chuck may include a chuck body, an electrode pattern, and a dielectric layer. The chuck body at least partially defines a plurality of opening parts and includes a plurality of first bars. Each of the plurality of first bars may extend in a first direction and be spaced apart from one another in a second direction intersecting with the first direction. In a plan view, each first bar may separate a pair of neighboring opening parts in the second direction. The electrode pattern may be on a first side of the chuck body. The dielectric layer may be on the first side of the chuck body and may cover the electrode pattern. In a plan view, the chuck body defines a peripheral region surrounding the opening parts. The electrode pattern may be on the peripheral region and the first bars.

### CROSS-REFERENCE TO RELATED APPLICATIONS

This application claims priority under 35 U.S.C. § 119 to Korean Patent Application No. 10-2025-0051389, filed on Apr. 21, 2025, in the Korean Intellectual Property Office, the entire contents of which are incorporated herein by reference.

### BACKGROUND

Example embodiments of the present disclosure relate to an electrostatic mask chuck configured to reduce warpage of a mask using electrostatic force, and a deposition apparatus including the same.

An electronic device, such as a smartphone, a digital camera, a laptop computer, a navigation, and a smart television, configured to provide an image to a user includes a display device configured to show an image.

A display device generates an image and provides the generated image to a user through a display screen.

As a display panel of a display device, various display panels, such as a liquid crystal display panel (LCD panel), and an organic light-emitting display panel (OLED panel), are being developed.

An organic light-emitting display panel includes light-emitting diodes capable of self-emission.

The light-emitting diodes each include an anode, a cathode, and a light-emission layer. The light-emission layer includes an organic material. A deposition process may be used in a method for forming the light-emission layer in the display panel.

The deposition process may be performed by placing a mask between a substrate of the display panel and a deposition source, and allowing an organic material supplied from the deposition source to be deposited on the substrate through a mask.

A fine metal mask (FMM) is used as the deposition mask, and a magnet plate is used to improve flatness of the fine metal mask and/or adhesion to the substrate.

A fine silicon mask (FSM) may also be used as another type of the deposition mask. The fine silicon mask is used for manufacture of an OLEDoS (OLED on Silicon) panel. The OLEDoS panel differs from a conventional OLED panel in terms of a substrate. The OLEDoS panel may have a relatively higher degree of integration by implementing an integrated circuit on a silicon semiconductor substrate, and a relatively higher resolution by forming an organic light-emitting diode on the silicon semiconductor substrate. Because the fine silicon mask is manufactured based on a silicon wafer and allows implementation of relatively denser pixels compared to a fine metal mask, the fine silicon mask is suitable for the manufacture of the OLEDoS panel.

However, because the fine silicon mask does not include a magnetic material, a magnetic material is added to the fine silicon mask to utilize a magnet plate, or an electrostatic chuck is used to chuck the fine silicon mask as an alternative to the magnet plate.

### SUMMARY

Example embodiments of the present disclosure provide an electrostatic mask chuck configured to reduce warpage of a mask using electrostatic force, and a deposition apparatus including the same.

According to some example embodiments, an electrostatic mask chuck may include a chuck body, an electrode pattern, and a dielectric layer. The chuck body at least partially defines a plurality of opening parts and comprising a plurality of first bars. Each of the plurality of first bars extend in a first direction and are spaced apart from one another in a second direction that intersects the first direction. In a plan view, each first bar of the plurality of first bars separates a pair of neighboring opening parts of the plurality of opening parts in the second direction. An electrode pattern is on a first side of the chuck body and a dielectric layer is on the first side of the chuck body and covering the electrode pattern. In a plan view, the chuck body defines a peripheral region surrounding the plurality of opening parts, and the electrode pattern is on the peripheral region and the plurality of first bars.

According to some example embodiments of the present disclosure, the electrode pattern extends in the first direction on each of the plurality of first bars and extends between the plurality of first bars and the peripheral region through both ends of each first bar.

According to some example embodiments of the present disclosure, the electrode pattern may be a straight line on each of the plurality of first bars.

According to some example embodiments of the present disclosure, wherein the electrode pattern comprises a first electrode pattern and a second electrode pattern, the first electrode pattern and the second electrode pattern each configured to receive power sources of different polarities. A pair of neighboring first bars of the plurality of first bars comprise a first sub bar and a second sub bar. The first electrode pattern is on the first sub bar, and the second electrode pattern is on the second sub bar.

According to some example embodiments of the present disclosure, the plurality of first bars of the electrode pattern are configured to receive a power source having a same polarity.

According to some example embodiments of the present disclosure, the electrode pattern comprises a first electrode pattern and a second electrode pattern, the first electrode pattern and the second electrode pattern configured to receive power sources of different polarities, a pair of neighboring first bars of the plurality of first bars comprise a first sub bar and a second sub bar, the first electrode pattern and the second electrode pattern are on the first sub bar, and wherein the first electrode pattern and the second electrode pattern are on the second sub bar.

According to some example embodiments of the present disclosure, in a plan view, the dielectric layer comprises a first portion overlapping the peripheral region, and second portions overlapping the plurality of first bars, and the first portion comprises a first opposing surface facing the chuck body and a first chuck surface opposite to the first opposing surface, the second portions each comprise a second opposing surface facing the chuck body and a second chuck surface opposite to the second opposing surface, and the first chuck surface and the second chuck surface are in a same plane.

According to some example embodiments of the present disclosure, the plurality of opening parts are symmetric with respect to each other about a first center line of the chuck body in a plan view, the first center line extending in the first direction.

According to some example embodiments of the present disclosure, the plurality of opening parts each have a symmetrical shape about a second center line of the chuck body in a plan view, the second center line extending in the second direction.

According to some example embodiments of the present disclosure, the plurality of opening parts comprise a first sub opening part and a second sub opening part neighboring the first sub opening part and farther away from the first center line than the first sub opening part. A length of the second sub opening part in the first direction is less than a length of the first sub opening part in the first direction.

According to some example embodiments of the present disclosure, the chuck body comprises a protruding part facing the second sub opening part in the first direction and the first sub opening part in the second direction. At least a portion of the electrode pattern is on the protruding part.

According to some example embodiments of the present disclosure, the electrode pattern comprises a first electrode pattern and a second electrode pattern the first electrode pattern and the second electrode pattern configured to receive different polarities, the first electrode pattern comprises first branch lines on the protruding part, the second electrode pattern comprises second branch lines on the protruding part, each first branch of the first branch lines extends in the second direction and the first branch lines face each other in the first direction, and each second branch line of the second branch lines extends in the second direction between a pair of neighboring first branch lines.

According to some example embodiments of the present disclosure, the chuck body further comprises a plurality of second bars, each second bar of the plurality of second bars extending in the second direction and connecting a pair of neighboring first bars of the plurality of first bars.

According to some example embodiments of the present disclosure, in a plan view, the electrode pattern does not overlap the plurality of second bars.

According to some example embodiments of the present disclosure, the dielectric layer comprises a first portion, second portions, and third portions, and, in a plan view, the first portion overlaps the peripheral region, the second portions overlap the plurality of first bars, and the third portions overlap the plurality of second bars, and the first portion comprises a first opposing surface facing the chuck body and a first chuck surface opposite to the first opposing surface, the second portions each comprise a second opposing surface facing the chuck body and a second chuck surface opposite to the second opposing surface, the third portions each comprise a third opposing surface facing the chuck body and a support surface opposite to the third opposing surface, and the first chuck surface, the second chuck surface and the support surface are in a same plane.

According to some example embodiments, an electrostatic mask chuck may include a chuck body, an electrode pattern, and a dielectric layer. The chuck body at least partially defines a plurality of opening parts and comprising a plurality of first bars, each of the plurality of first bars extend in a first direction and are spaced apart from one another in a second direction intersecting the first direction. In a plan view, each first bar of plurality of first bars separates a pair of neighboring opening parts of the plurality of opening parts in the second direction. The electrode pattern may be on a first side of the chuck body. The dielectric layer may be on the first side of the chuck body to cover the electrode pattern. In a plan view, the chuck body defines a peripheral region surrounding the plurality of opening parts. The dielectric layer comprises a first portion and second portions, and, in a plan view, the first portion overlaps the peripheral region and the second portions overlap the plurality of first bars. The first portion comprises a first opposing surface facing the chuck body and a first chuck surface opposite to the first opposing surface, the second portions each comprise a second opposing surface facing the chuck body and a second chuck surface opposite to the second opposing surface, and the first chuck surface and the second chuck surface are in a same plane.

According to some example embodiments, a deposition apparatus may include a mask, a deposition source, and an electrostatic mask chuck. The deposition source may be configured to discharge a deposition material towards the mask. The electrostatic mask chuck may be between the mask and the deposition source, and the mask may be attached to the electrostatic mask chuck. The electrostatic mask chuck may include a chuck body, an electrode pattern, and a dielectric layer. The chuck body at least partially defining a plurality of first opening parts and comprising a plurality of first bars, each of the plurality of first bars extending in a first direction and spaced apart from one another in a second direction intersecting the first direction. In a plan view, each first bar of the plurality of first bars separates a pair of neighboring first opening parts of the plurality of first opening parts in the second direction. The electrode pattern may be on a first side of the chuck body. The dielectric layer may be on the first side of the chuck body and covering the electrode pattern. In a plan view, the chuck body defines a peripheral region surrounding the plurality of first opening parts. The electrode pattern is on the peripheral region and the plurality of first bars.

According to some example embodiments of the present disclosure, the mask comprises a first surface facing the electrostatic mask chuck, and a second surface opposite to the first surface, the first surface defines second opening parts, and, in a plan view, the plurality of first opening parts cover the second opening parts.

According to some example embodiments of the present disclosure, in a plan view, the peripheral region and the plurality of first bars do not overlap the second opening parts.

According to some example embodiments of the present disclosure, the mask may include silicon wafer and the silicon wafer may define the second opening parts.

According to some example embodiments of the present disclosure, the mask may be flatly or planarly supported by the peripheral region of the chuck body and by the first bars to reduce warpage of the mask.

According to some example embodiments, a method of operating a deposition apparatus may comprise arranging a mask on an electrostatic mask chuck of the deposition apparatus; arranging a substrate on a substrate chuck of the deposition apparatus, the deposition apparatus including the electrostatic mask chuck and the substrate chuck opposite each other in a chamber of the deposition apparatus, and the mask and the substrate facing each other; and operating a deposition source of the deposition apparatus to deposit deposition material on the substrate, the electrostatic mask chuck being between the mask and the deposition source, and the deposition material passing through pattern holes of the mask and depositing on the substrate. The electrostatic mask chuck comprises a chuck body at least partially defining a plurality of opening parts and comprising a plurality of first bars, each of the plurality of first bars extending in a first direction and spaced apart from one another in a second direction, the second direction intersecting the first direction, wherein, in a plan view, each first bar of the plurality of first bars separates a pair of neighboring opening parts of the plurality of opening parts in the second direction; an electrode pattern on a first side of the chuck body; and a dielectric layer on the first side of the chuck body and covering the electrode pattern. In a plan view, the chuck body defines a peripheral region surrounding the plurality of opening parts, and the electrode pattern is on the peripheral region and the plurality of first bars.

According to some example embodiments of the present disclosure, the mask comprises a first surface facing the electrostatic mask chuck, and a second surface opposite to the first surface. The first surface defines second opening parts. In a plan view, the plurality of first opening parts cover the second opening parts.

According to some example embodiments of the present disclosure, in a plan view, the peripheral region and the plurality of first bars do not overlap the second opening parts.

According to some example embodiments of the present disclosure, the mask comprises silicon wafer and the silicon wafer defines the second opening parts.

In addition, the electrode pattern configured to generate electrostatic force may be disposed on the peripheral region of the chuck body and the first bars and the electrode pattern may increase an area of the chuck surface. The mask is fixed or secured by the electrostatic force.

### BRIEF DESCRIPTION OF THE DRAWINGS

These and/or other features will become apparent and more readily appreciated from the following description of the example embodiments, taken in conjunction with the accompanying drawings in which:

FIG. 1 is a plan view showing an electrostatic mask chuck according to some example embodiments of the present disclosure.

FIG. 2 illustrates the chuck body of FIG. 1.

FIG. 3 illustrates an electrode pattern disposed on a first side of the chuck body shown in FIG. 2.

FIG. 4 is a magnified view of the A section shown in FIG. 3.

FIG. 5 is a cross-sectional view taken along the I-I′ line of FIG. 1.

FIG. 6 is a magnified view of the B section shown in FIG. 1.

FIG. 7 illustrates a modified example of the electrode pattern disposition shown in FIG. 6.

FIG. 8 illustrates a modified example of the electrode pattern disposition shown in FIG. 6.

FIG. 9 illustrates a modified example of the electrostatic mask chuck shown in FIG. 1.

FIG. 10 is a cross-sectional view taken along the II-II′ line of FIG. 9.

FIG. 11 illustrates a deposition apparatus according to some example embodiments of the present disclosure.

FIG. 12 is a plan view illustrating the mask shown in FIG. 11.

FIG. 13 is a magnified view of the portion C shown in FIG. 12.

FIG. 14 is a cross-sectional view taken along the III-III′ of FIG. 13.

FIG. 15 is a plan view illustrating a mask attached to the electrostatic mask chuck shown in FIG. 11.

FIG. 16 illustrates a display panel manufactured by a deposition apparatus according to some example embodiments of the present disclosure.

FIG. 17 is a block diagram of an electronic device according to some example embodiments of the present disclosure.

FIG. 18 are schematic diagrams of electronic devices according to some example embodiments.

### DETAILED DESCRIPTION

References will now be made in detail to some example embodiments, of which examples are illustrated in the accompanying drawings, where like reference numerals refer to like elements throughout. The example embodiments may have a variety of forms and permutations, but the present disclosure shall by no means be construed as being limited to the described embodiments. Rather, the present disclosure shall be construed to encompass all forms, permutations, equivalents, and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The exemplary term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The exemplary term “below” or “beneath” can therefore encompass an orientation of both above and below.

Furthermore, when one device or layer is described to be “on,” “over,” “above,” and the like, another device or layer, it shall also encompass the case of yet another device or layer disposed on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part, or combinations thereof, and shall not be construed to preclude any possibility of presence or addition of one or more other characteristics, numbers, steps, operations, elements, parts, or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

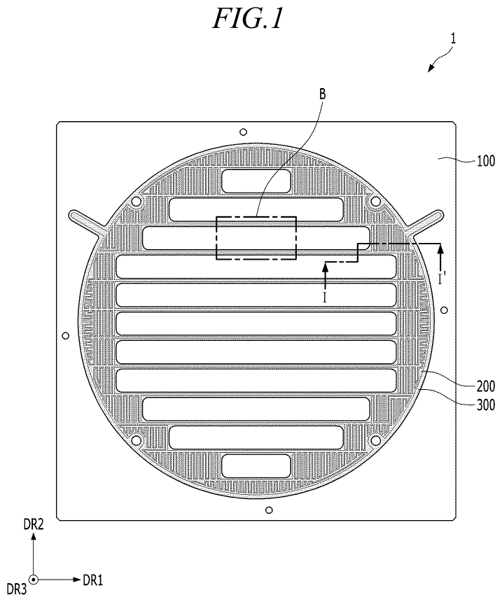

In some example embodiments of the present disclosure, directions labeled as first through third directions DR1-DR3 may be defined. The first direction DR1 may be parallel to a side (or a surface) of a chuck body 100 (FIG. 1) of an electrostatic mask chuck 1 (FIG. 1). The second direction DR2 may intersect the first direction DR1 and may be parallel to the side (or the surface) of the chuck body 100. The third direction DR3 may intersect the first direction DR1 and the second direction DR2 and may be perpendicular to the surface of the chuck body 100. In some example embodiments of the present disclosure, the phrase “in a plan view” refers to viewing along the third direction DR3.

FIG. 1 is a plan view illustrating an electrostatic mask chuck according to some example embodiments of the present disclosure.

Referring to FIG. 1, the electrostatic mask chuck 1, according to some example embodiments of the present disclosure, is a device configured to chuck or de-chuck a mask by electrostatic force, and may include a chuck body 100, an electrode pattern 200, and a dielectric layer 300.

As described herein, the mask may be a fine silicon mask, but example embodiments are not limited thereto.

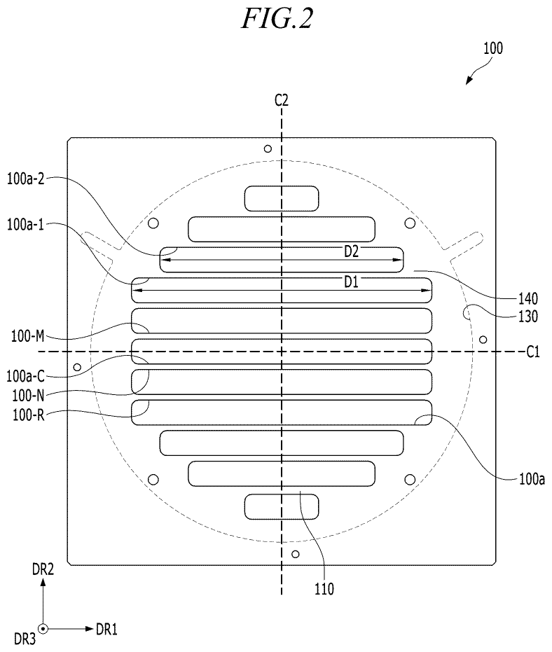

FIG. 2 is an illustration of the chuck body shown in FIG. 1.

Referring to FIG. 2, the chuck body 100 may provide, include, or otherwise define first opening parts 100a.

The first opening parts 100a may each be through holes formed on one side of the chuck body 100 to penetrate the chuck body 100 in the third direction DR3.

As a result, a deposition material may be provided to second opening parts provided on a mask through the first opening parts 100a.

The first opening parts 100a may each extend in the first direction DR1, and the first opening parts 100a may be disposed to be spaced apart from one another in the second direction DR2.

The first opening parts 100a may be symmetrically disposed about a first center line C1 of the chuck body 100 in a plan view. Here, the first center line C1 may refer to an imaginary straight line passing through a center of the chuck body 100 and extending in the first direction DR1.

As described herein, the center of the chuck body 100 may refer to a center of the peripheral region 130.

The first opening parts 100a may each have a symmetrical shape about a second center line C2 of the chuck body 100 in a plan view. Here, the second center line C2 may refer to an imaginary straight line passing through a center of the chuck body 100 and extending in the second direction DR2.

The first opening parts 100a may each have a shape, such as a rectangular shape, having a length in the first direction DR1 longer than a width in the second direction DR2.

As described herein, “a rectangular” shape may indicate a shape that is a rectangle, but also indicates shapes similar to a rectangle in which each of the corners are curved or rounded.

Although eleven first opening parts 100a are illustrated, the number of first opening parts 100a is not limited thereto.

The chuck body 100 may include first bars 110 separating the first opening parts 100a from each other in a plan view.

The first bars 110 may each extend in the first direction DR1, and the first bars may be disposed to be spaced apart from each other in the second direction DR2.

The first bars 110 may each separate a pair of first opening parts 100a neighboring (e.g., immediately neighboring) in the second direction DR2 among the first opening parts 100a in a plan view.

The first bars 110 may be configured to flatly or planarly support a central portion of the mask fixed to the electrostatic mask chuck 1.

Although ten first bars 110 are illustrated, the number of first bars 110 is not limited thereto, and may vary depending on the number of first opening parts 100a, for example.

In the chuck body 100, a peripheral region 130 may be defined surrounding the first opening parts 100a in a plan view.

The peripheral region 130 may refer to a portion overlapping with the dielectric layer 300 in a generally ring (or circular) shape surrounding the first opening parts 100a in a plan view. An outer boundary (e.g., a radially outer boundary) of the peripheral region 130 is indicated by a dashed line for ease of understanding.

The first bars 110 may each have both ends connected to the peripheral region 130 and be integrally formed with the peripheral region 130.

In some example embodiments, the chuck body 100 may include or otherwise define protruding parts 140. The protruding parts 140 may be disposed on an inner portion of the peripheral region 130 and spaced from the outer boundary of the peripheral region 130. Accordingly, an inner surface of the peripheral region 130 may have a stair shape, rather than a circular shape, due to the protruding parts 140.

Describing the protruding parts 140 in relation to the first opening parts 100a, the farther the first opening parts 100a are disposed from the first center line C1 in the second direction DR2, the shorter length of the first opening parts 100a may be in the first direction DR1, and the protruding parts 140 may be provided or otherwise defined due to difference in length in the first direction DR1 between a pair of first opening parts 100a adjacent to each other. The lengths of the first opening parts 100a farther away from the first center line C1 may be shortened to account for the curvature of the peripheral region 130, and thereby maintain a desired distance (e.g., minimum distance) of the first opening parts 100a from the outer boundary of the peripheral region 130. One or more first opening parts 100a closer to the first center line C1 may have the longest lengths among the first opening parts 100a defined in the peripheral region 130, and one or more first opening parts 100a that are the farthest from the first center line C1 may have the shortest lengths among the first opening parts 100a defined in the peripheral region 130.

For example, the first opening parts 100a may include a first sub opening part 100a-1 and a second sub opening part 100a-2. The first sub opening part 100a-1 and the second sub opening part 100a-2 may each be one of the first opening parts 100a. The second sub opening part 100a-2 may be immediately neighboring the first sub opening part 100a-1 and disposed farther from the first center line C1 in the second direction DR2 than the first sub opening part 100a-1. A second length D2 of the second sub opening part 100a-2 in the first direction DR1 may be shorter than a first length D1 of the first sub opening part 100a-1 in the first direction DR1. As a result, a protruding part 140 facing (or immediately adjacent to) the second sub opening part 100a-2 in the first direction DR1 and the first sub opening part 100a-1 in the second direction DR2 may be formed or defined in an inner portion of the peripheral region 130.

As is understood from the discussion above and FIG. 2, protruding parts 140 may be present on opposite ends of the first sub opening part 100a-1 and the second sub opening part 100a-2 in the first direction DR1. Accordingly, the chuck body 100 may include twelve protruding parts 140. Although twelve protruding parts 140 are illustrated, the number of protruding parts 140 is not limited thereto.

As illustrated, the first opening part 100a-C in the center (e.g., the centermost first opening part 100a-C) and along the first center line C1 may be located about the first center line C1. One or more first opening parts 100a adjacent to the centermost first opening part 100a-C in the second direction DR2 may have a same length as the centermost first opening part 100a-C. For example, the first opening parts 100a-1, 100-M, 100-N, and 100-R adjacent to the centermost first opening part 100a-C along the second center line C2 may have a same length as the centermost first opening parts 100a-C. Although FIG. 2 illustrates four first opening parts 100a-1, 100-M, 100-N, and 100-R adjacent to the centermost first opening part 100a-C having the same length as the centermost first opening part 100a-C, the number of first opening parts having the same length as the centermost first opening part 100a-C may be more than four or less than four.

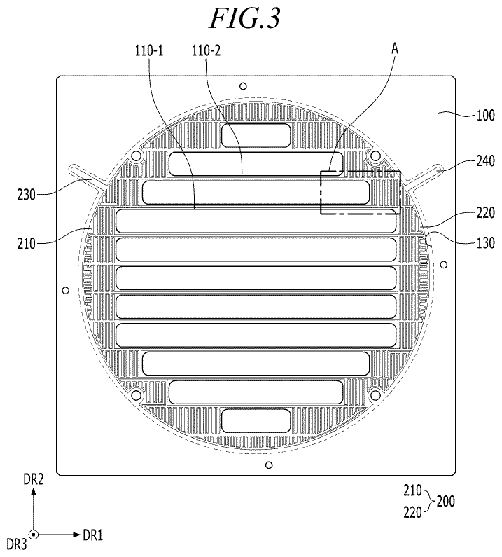

FIG. 3 illustrates an electrode pattern disposed on a first side (or surface) of the chuck body shown in FIG. 2.

Referring to FIG. 3, the electrode pattern 200 may be disposed on one surface of the chuck body 100.

The electrode pattern 200 may be disposed on the first bars 110 and the peripheral region 130. As a result, an area of a chuck surface, where a mask is fixed or secured by electrostatic force, may be increased in comparison to a case where the electrode pattern 200 is disposed only on the peripheral region 130, and an electrostatic force may be applied even to a central portion of a mask by the electrode pattern 200 disposed on the first bars 110.

The electrode pattern 200 may be disposed across each of the first bars 110 in the first direction DR1.

For example, the electrode pattern 200 may extend on the first bars 110 in the first direction DR1 and extend from the first bars 110 to the peripheral region 130 through both ends of each of the first bars 110.

The electrode pattern 200 may be provided as one or single straight line on each of the first bars 110.

As a result, a width of each of the first bars 110 in the second direction DR2 may be minimized or reduced, and an increase in the width of each of the first bars 110 due to disposition of the electrode pattern 200 may be minimized or reduced.

Accordingly, a shadowing effect, in which movement or flow of a disposition material is impeded, restricted or hindered by the first bars 110, may be effectively suppressed or reduced.

In some example embodiments, a width of the electrode pattern 200 in the second direction DR2 on each of the first bars 110 may be 1.2 mm (or about 1.2 mm), and a width of each of the first bars in the second direction DR2 may be less than or equal to 5 mm (or about 5 mm), but example embodiments are not limited thereto.

The electrode pattern 200 may be provided with or may receive power sources of different polarities on the first bars 110.

For example, the electrode pattern 200 may include a first electrode pattern 210 and a second electrode pattern 220 to which power sources of different polarities are applied or provided. The first electrode pattern 210 may be disposed on a first sub bar 110-1, which is one of a pair of neighboring (e.g., immediately neighboring) first bars 110, and the second electrode pattern 220 may be disposed on a second sub bar 110-2, which is the other of the pair of neighboring first bars 110.

In some example embodiments, the first electrode pattern 210 may be applied with or may receive a positive power source, and the second electrode pattern 220 may be applied with or may receive a negative power source.

In some example embodiments, the electrode pattern 200 may further include a first power terminal 230 and a second power terminal 240.

The first power terminal 230 may be connected to the first electrode pattern 210 to supply a positive power source. The second power terminal 240 may be connected to the second electrode pattern 220 to supply a negative power source. The first power terminal 230 and the second power terminal 240 may be disposed on one surface or side of the chuck body 100, but example embodiments are not limited thereto.

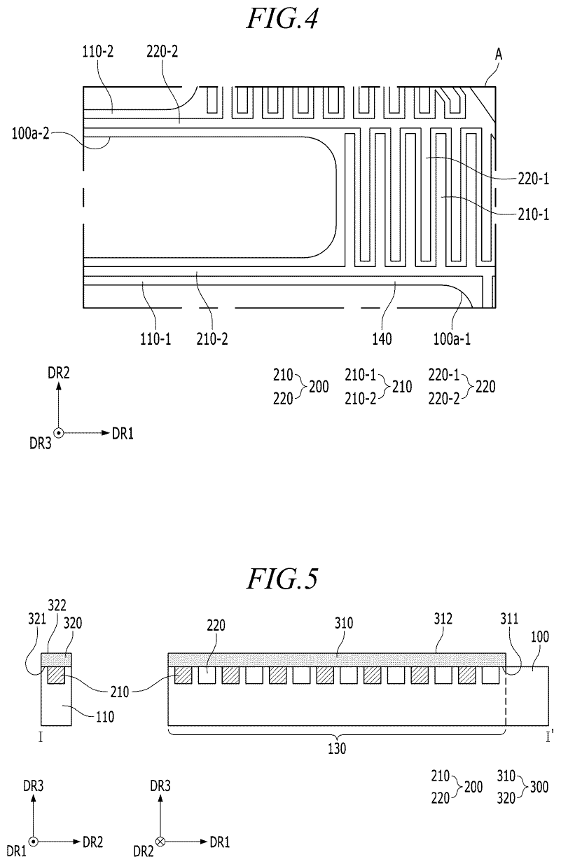

FIG. 4 is a magnified view of the A section shown in FIG. 3.

Referring to FIG. 4, at least one portion of the electrode pattern 200 may be disposed on the protruding part 140.

The protruding part 140 may be a portion of the chuck body 100 or the peripheral region 130 and face the second sub opening part 100a-2 in the first direction DR1 and the first sub opening part 100a-1 in the second direction DR2.

As a result, an area of the chuck surface where the mask is fixed by electrostatic force may be increased by an area of the protruding parts 140, and flatness of the mask and warpage of the mask may be reduced.

In some example embodiments, the first electrode pattern 210 may include first branch lines 210-1 disposed on the protruding part 140, and the second electrode pattern 220 may include second branch lines 220-1 disposed on the protruding part 140.

The first branch lines 210-1 may each extend in the second direction DR2 and face each other in the first direction DR1.

The second branch lines 220-1 may extend in the second direction DR2 between a pair of neighboring first branch lines 210-1 among the first branch lines 210-1. The first branch lines 210-1 and the second branch lines 220-1 may form an interleaving pattern.

The first electrode pattern 210 may include a first straight line 210-2 extending in the first direction DR1 from the first sub bar 110-1 to the peripheral region 130. The first branch lines 210-1 may each be branched from the first straight line 210-2 in the second direction DR2. The second electrode pattern 220 may include a second straight line 220-2 extending along the first direction DR1 from the second sub bar 110-2 to the peripheral region 130. The second branch lines 220-1 may each be branched from the second straight line 220-2 in the second direction DR2.

FIG. 5 is a cross-sectional view taken along the I-I′ line shown in FIG. 1.

In FIG. 5, for ease of understanding, an outer boundary of the peripheral region 130 is indicated with a dashed line, and hatching is added to distinguish the first electrode pattern 210 from the second electrode pattern 220.

Referring to FIG. 1 and FIG. 5, the dielectric layer 300 may be disposed on one side or surface of the chuck body 100 to cover the electrode pattern 200.

The dielectric layer 300 may include a first portion 310 and second portions 320. The first portion 310 may be a portion overlapping with the peripheral region 130 in a plan view, and the second portions 320 may be portions overlapping with the first bars 110 in a plan view.

The first portion 310 may include a first opposing surface 311 and a first chuck surface 312.

The first opposing surface 311 may be a surface facing the chuck body 100, and the first chuck surface 312 may be a surface opposite to the first opposing surface 311 and facing the mask.

The second portions 320 may each include a second opposing surface 321 and a second chuck surface 322.

The second opposing surface 321 may be a surface facing the chuck body 100, and the second chuck surface 322 may be a surface opposite to the second opposing surface 321 and facing the mask.

The first chuck surface 312 and the second chuck surface 322 may be disposed substantially on a same plane (or substantially coplanar).

As a result, a central portion and a peripheral portion of the mask may be flatly or planarly supported by the first chuck surface 312 and the second chuck surfaces 322 and fixed or secured on the first chuck surface 312 and the second chuck surfaces 322 by electrostatic force. Therefore, flatness or planarity of the mask may be improved and warpage of the mask may be reduced.

It is illustrated that a pattern groove receiving the electrode pattern 200 is formed on one side of the chuck body 100, but example embodiments are not limited thereto. The electrode pattern 200 may be patterned on one side of the chuck body 100.

In some example embodiments, thicknesses of the first bars 110 and the peripheral region 130 in the third direction DR3 may each be 9 mm (or about 9 mm), and a spacing between the first electrode pattern 210 and the second electrode pattern 220 may be smaller than or equal to 1.2 mm, but example embodiments are not limited thereto.

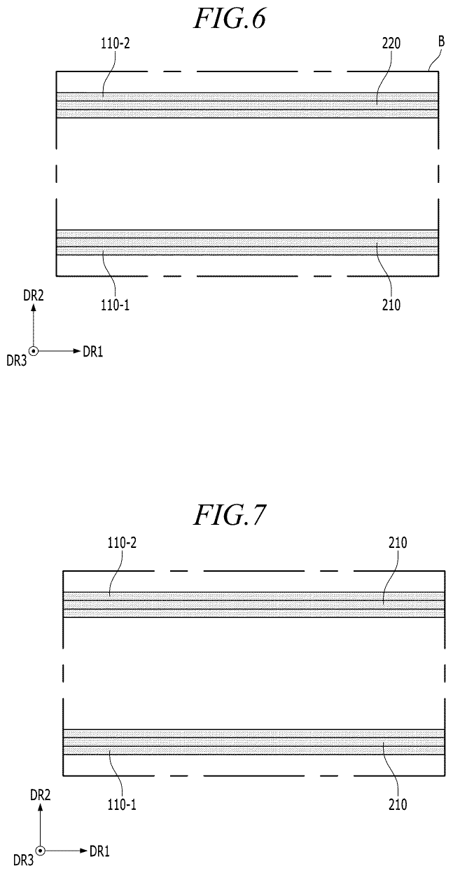

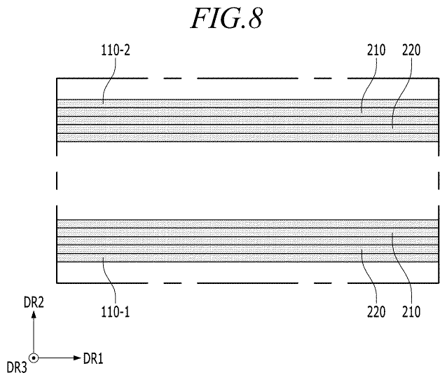

FIG. 6 is a magnified view of the B section shown in FIG. 1, and FIG. 7 illustrates a modified example of the electrode pattern disposition or arrangement shown in FIG. 6.

Referring to FIG. 6 and FIG. 7, the electrode pattern 200 may be applied with or receive power sources of different polarities on the first bars 110 (see FIG. 6), or with power sources of a same polarity on the first bars 110 (see FIG. 7). In some example embodiments, and as FIG. 6, the second electrode pattern 220 is on a second sub bar 110-2 and the first electrode pattern 210 is on the first sub bar 110-1.

In some example embodiments, and as illustrated in FIG. 7, a first electrode pattern 210 may be disposed on each of the first bars 110.

For example, a first electrode pattern 210 may be disposed on each of the first sub bar 110-1 and the second sub bar 110-2, which are a pair of neighboring (or immediately neighboring) first bars 110.

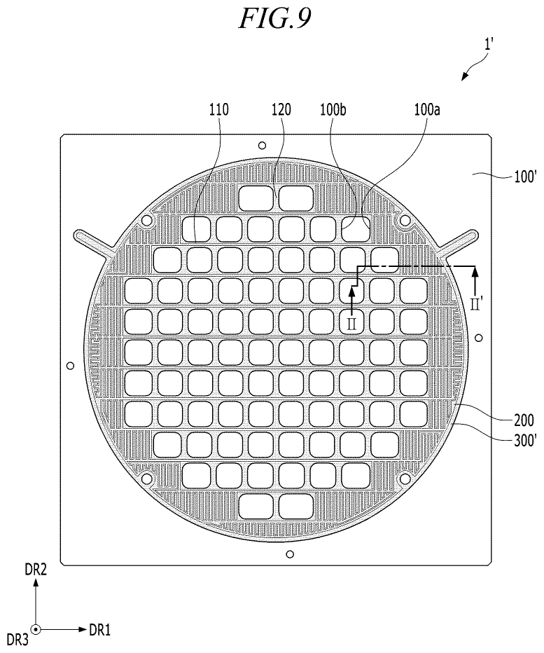

FIG. 8 illustrates a modified example of the electrode pattern disposition or arrangement shown in FIG. 6.

Referring to FIG. 8, the electrode pattern 200 may be provided as two or more straight lines on each of the first bars 110.

In some example embodiments, the first electrode pattern 210 and the second electrode pattern 220 may be disposed on each of the first bars 110 as shown in FIG. 8.

For example, a first electrode pattern 210 and a second electrode pattern 220 may be disposed on a first sub bar 110-1, which is one of a pair of neighboring first bars 110, and a first electrode pattern 210 and a second electrode pattern 220 may also be disposed on a second sub bar 110-2, which is the other of the pair of neighboring first bars 110.

In the modified example, on each of the first bars 110, a width of the first electrode pattern 210 in the second direction DR2 and a width of the second electrode pattern 220 in the second direction DR2 may each be 1.2 mm (or about 1.2 mm), a spacing between the first electrode pattern 210 and the second electrode pattern 220 on each of the first bars 110 may be less than or equal to 1.2 mm (or about 1.2 mm), and a width of each of the first bars 110 in the second direction DR2 may be more than or equal to 5 mm (or about 5 mm), but example embodiments are not limited thereto.

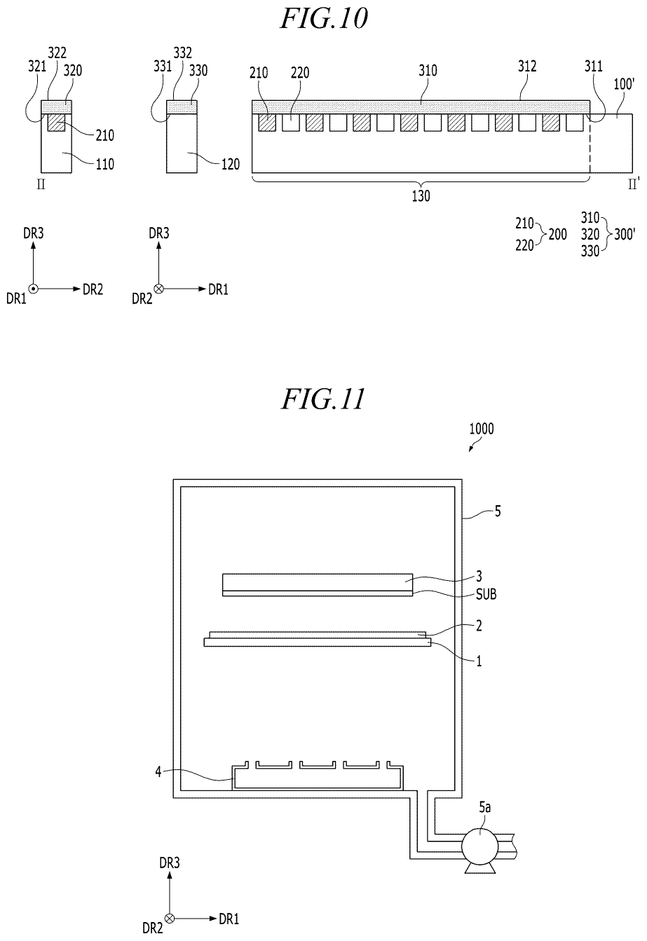

FIG. 9 illustrates a modified example of the electrostatic mask chuck shown in FIG. 1, and FIG. 10 is a cross-sectional view taken along the II-II′ line shown in FIG. 9.

In FIG. 10, for ease of understanding, an outer boundary of the peripheral region 130 is indicated with a dashed line.

Referring to FIG. 9 and FIG. 10, the chuck body 100′ of the electrostatic mask chuck 1′ may further include second bars 120, and the second bars 120 may each extend in the second direction DR2 to connect a pair of neighboring first bars 110 among the first bars 110.

The second bars 120 may each be disposed across the first opening part 100a in the second direction DR2.

The first opening parts 100a may each be divided into segmented regions 100b by the second bars 120, and the segmented regions 100b may be disposed to be spaced apart from one another along the first direction DR1.

The second bars 120 may improve flatness of the mask fixed or secured to the electrostatic mask chuck 1′.

The electrode pattern 200 may not be disposed on the second bars 120. The electrode pattern 200 may not overlap with the second bars 120 in a plan view.

The dielectric layer 300′ may include a first portion 310, second portions 320, and third portions 330.

The first portion 310 may be a portion overlapping with the peripheral region 130 in a plan view, the second portions 320 may be portions overlapping with the first bars 110 in a plan view, and the third portions 330 may be portions overlapping with the second bars 120 in a plan view.

The first portion 310 may include a first opposing surface 311 and a first chuck surface 312.

The first opposing surface 311 may be a surface facing (and in contact with) the chuck body 100′, and the first chuck surface 312 may be a surface opposite to the first opposing surface 311 and facing the mask and in contact with the mask when the mask is placed on the chuck 1.

The second portions 320 may each include a second opposing surface 321 and a second chuck surface 322.

The second opposing surface 321 may be a surface facing the chuck body 100', and the second chuck surface 322 may be a surface opposite to the second opposing surface 3221 and facing the mask.

The third portions 330 may each include a third opposing surface 331 and a support surface 332.

The third opposing surface 331 may be a surface facing the chuck body 100', and the support surface 332 may be a surface opposite to the third opposing surface 331 and facing the mask.

The first chuck surface 312, the second chuck surface 322, and the support surface 332 may be disposed substantially on a same plane.

As a result, a central portion and a peripheral portion of the mask may be flatly supported by the first chuck surface 312, the second chuck surfaces 322, and the support surfaces 332 and fixed by the first chuck surface 312 and the second chuck surfaces 322 by electrostatic force. Therefore, flatness of the mask may be improved and warpage of the mask may be reduced.

It is illustrated that a pattern groove receiving the electrode pattern 200 is formed on one side or surface of the chuck body 100′, but example embodiments are not limited thereto. The electrode pattern 200 may be patterned on an opposite surface of the chuck body 100′.

FIG. 11 is an illustration of a deposition apparatus according to some example embodiments of the present disclosure.

Referring to FIG. 11, a deposition apparatus 1000 (or a substrate processing apparatus) according to some example embodiments of the present disclosure may include an electrostatic mask chuck 1, a mask 2, an electrostatic substrate chuck 3, a deposition source 4, and a vacuum chamber 5. However, example embodiments are not limited thereto, and one or of the elements of the deposition apparatus 1000 may be omitted.

The electrostatic mask chuck 1 may be disposed in the vacuum chamber 5 and between the mask 2 and the deposition source 4, and the mask 2 may be attached or secured to the electrostatic mask chuck 1 by electrostatic force.

The mask 2 may be transported to the electrostatic mask chuck 1 by a first transport device, for example, and may be installed or arranged on the electrostatic mask chuck 1. For example, the mask 2 may be transported to and from the electrostatic mask chuck 1 and/or the deposition apparatus 1000.

As described herein, “a transport device” may be a transport device used with a deposition apparatus in a manufacture line of a display panel, and may include robotic arms, for example, but example embodiments are not limited thereto.

Features described with references to FIG. 1 through FIG. 10 may be used with or incorporated in the electrostatic mask chuck 1, and a detailed descriptions thereof will be omitted for the sake of brevity.

The electrostatic substrate chuck 3 (for example, which may be similar in some respects to the electrostatic substrate chuck 1) may be disposed within the vacuum chamber 5 on an opposite side of the deposition source 4 with respect to the mask 2, and a substrate SUB may be attached or secured to the electrostatic substrate chuck 3 by electrostatic force.

The substrate SUB may be referred to as a mother substrate, for example, for manufacture of a display panel, which will be described below. The substrate SUB may be provided with cell regions, and the cell regions may each form one display panel after a cutting process is performed on the substrate SUB.

The substrate SUB may be supported by a substrate support before being attached to the electrostatic substrate chuck 3.

The substrate SUB may be transported by a second transport device, for example, for installing or arranging the substrate SUB on the electrostatic substrate chuck 3. The substrate SUB may be transported using robotic arms, for example.

In some example embodiments, the substrate SUB may descend or may be lowered while being attached or secured to the electrostatic substrate chuck 3 to be mounted on the mask 2, and subsequently, deposition of a deposition material discharged from the deposition source 4 may be performed. Here, the mask 2 may be attached or secured to the electrostatic mask chuck 1.

The deposition source 4 may be disposed in the vacuum chamber 5. The deposition source 4 may be configured to discharge a deposition material towards the mask 2. The deposition source 4 may include a crucible, a heater, and a nozzle. The crucible may store a deposition material. The heater may be configured to heat the deposition material stored in the crucible. The nozzle may be configured to discharge the deposition material vaporized in the crucible toward the mask 2.

The deposition material discharged from the deposition source 4 may pass through pattern holes of the mask 2 and may be deposited on the substrate SUB.

The vacuum chamber 5 may provide a sealed (e.g., hermetically sealed) internal space, where the electrostatic mask chuck 1, the mask 2, the electrostatic substrate chuck 3, and the deposition source 4 are disposed. A vacuum pump 5a may be connected to the vacuum chamber 5. The vacuum pump 5a may be configured to lower a pressure within the internal space of the vacuum chamber 5, for example, by evacuating the air within the vacuum chamber 5.

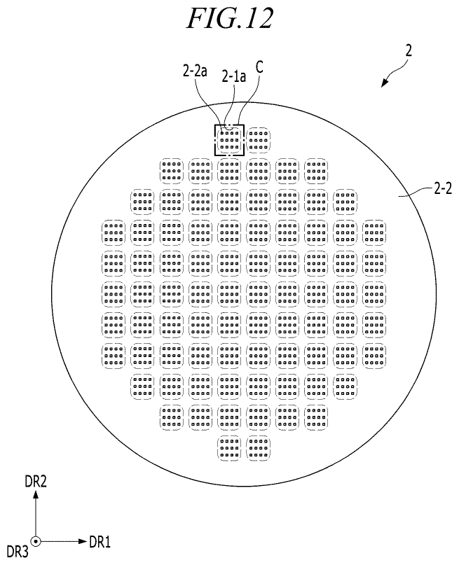

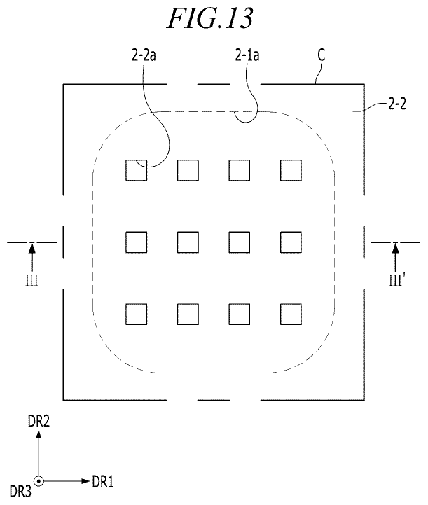

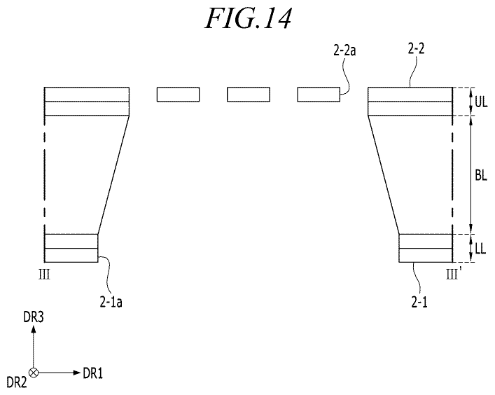

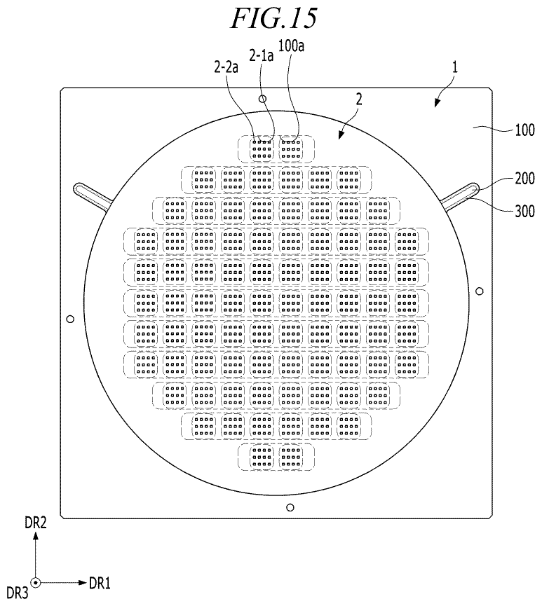

FIG. 12 is a plan view illustrating the mask shown in FIG. 11, FIG. 13 is a magnified view of the portion C shown in FIG. 12, and FIG. 14 is a cross-sectional view taken along the III-III′ line shown in FIG. 13.

In FIG. 12 and FIG. 13, for ease of understanding, second opening parts 2-1a, which are not visible in the plan view, are indicated with dashed lines.

Referring to FIG. 12 through FIG. 14, the mask 2 may include a first surface 2-1, and a second surface 2-2 opposite to the first surface 2-1. The first surface 2-1 may be a surface facing the electrostatic mask chuck 1.

The first surface 2-1 may be provided with the second opening parts 2-1a.

The second opening parts 2-1a may correspond to the cell regions of the substrate SUB on which the deposition material discharged from the deposition source 4 is deposited. The second opening parts 2-1a may overlap with the cell regions of the substrate SUB in a plan view.

The second opening parts 2-1a may each be connected to (e.g., fluidly connected to) the pattern holes 2-2a provided on the second surface 2-2.

Therefore, the deposition material may sequentially pass through the second opening part 2-1a and the pattern holes 2-2a to be deposited on the cell regions of the substrate SUB.

In some example embodiments, and as illustrated in FIG. 14, the mask 2 may include an upper layer UL, a base layer BL, and a lower layer LL.

The upper layer UL may at least partially include (or define) the second surface 2-2 of the mask 2, and the pattern holes 2-2a may be provided on the upper layer UL.

In some example embodiments, the upper layer UL may include two inorganic layers, and the pattern holes 2-2a may be provided only on an upper layer facing the substrate SUB among the two inorganic layers of the upper layer UL.

One inorganic layer among the two inorganic layers composing the upper layer UL may include silicon nitride, and the other inorganic layer may include silicon oxide.

The base layer BL may be disposed on a lower surface of the upper layer UL and include silicon monocrystal. The base layer BL may be a silicon wafer composed of or including silicon monocrystal.

However, example embodiments are not limited thereto, and the base layer BL may include, for example, a polymer material, polysilicon, and amorphous silicon.

The lower layer LL may be disposed on a lower surface of the base layer BL and may include or define the first surface 2-1 of the mask 2.

The second opening part 2-1a may be provided on the lower layer LL and extend to the base layer BL and may further extend to a lower layer that faces the base layer BL of the two inorganic layers included in the upper layer UL. The second opening part 2-1a may thus be fluidly connected to the pattern holes 2-2a.

In some example embodiments, the lower layer LL may be composed of two inorganic layers. One inorganic layer among the two inorganic layers of the lower layer LL may include silicon nitride, and the other inorganic layer may include silicon oxide.

FIG. 15 is a plan view illustrating the mask attached to the electrostatic mask chuck 1 shown in FIG. 11.

In FIG. 15, for ease of understanding, first opening parts 100a and second opening parts 2-1a, which are not visible in the plan view, are indicated with dashed lines.

Referring to FIG. 15, the first opening parts 100a may cover or overlap (e.g., vertically overlap) the second opening parts 2-1a in a plan view. The first bars 110 and the peripheral region 130 of the chuck body 100 of the electrostatic mask chuck 1 may not overlap (e.g., may be horizontally offset) with the second opening parts 2-1a in a plan view.

As a result, the movement or flow of the deposition material from the deposition source 4 to the second opening parts 2-1a may not be interrupted or impeded by the first bars 110 and the peripheral region 130. The first bars 110 and the peripheral region 130 may overlap with the first surface 2-1 of the mask 2 in a plan view.

In some example embodiments, when the electrostatic mask chuck 1′ shown in FIG. 9 is used in the deposition apparatus 1000 shown in FIG. 11, the segmented regions 100b may cover the second opening parts 2-1a in a plan view. The first bars 110, the second bars 120, and the peripheral region 130 of the chuck body 100′ of the electrostatic mask chuck 1′ may not overlap with the second opening parts 2-1a in a plan view.

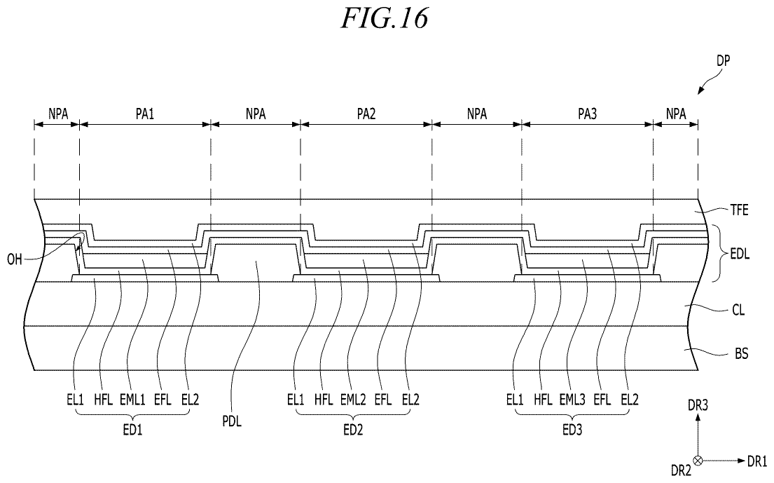

FIG. 16 illustrates a display panel manufactured using a deposition apparatus according to some example embodiments of the present disclosure.

Hereinafter, a first direction DR1 through a third direction DR3 may be defined as above or as follows. The first direction DR1 may be a direction parallel to one surface of a display panel DP. The second direction DR2 may be a direction intersecting the first direction DR1 and parallel to the one surface of the display panel DP. The third direction DR3 may be a direction perpendicular to the one surface of the display panel DP. The first direction DR1, the second direction DR2, and the third direction DR3 are therefore orthogonal to each other.

Referring to FIG. 16, a display device according to some example embodiments of the present disclosure may be an image display device and include a display panel DP. The display panel DP may include a base substrate BS, a circuit layer CL, a display device layer EDL, and an encapsulation layer TFE.

The base substrate BS may provide a base surface, and the circuit layer CL is disposed on the base substrate BS.

The base substrate BS may include a semiconductor wafer. In some example embodiments, the base substrate BS may include any one of a silicon wafer, a compound semiconductor wafer, a silicon carbide wafer, a sapphire wafer, a diamond wafer, a combination thereof, and the like.

The circuit layer CL may be disposed on the base substrate BS and include a pixel circuit and a signal wire.

The pixel circuit may include pixel transistors configured to drive light-emitting diodes.

In addition, the circuit layer CL may include peripheral transistors disposed on a non-display region of the display panel DP and configured to output a signal for controlling the pixel transistors of the pixel circuit.

In some example embodiments, the display panel DP may have a display region and a non-display region defined therein. The display region is a region where an image is displayed, and the non-display region is a region disposed around the display region, where no image is displayed.

Pixels for displaying an image may be disposed in the display region. The pixels may each include a light-emitting diode and a pixel circuit. The pixel circuit may be configured to control driving of the light-emitting diode.

In some example embodiments, some elements of the pixel transistor or the peripheral transistor may be included in the base substrate BS.

In some example embodiments, the base substrate BS may include channel regions and source drain regions of the pixel transistor or the peripheral transistor. The channel regions and the source drain regions may each be a semiconductor formed by doping an impurity on the base substrate BS.

The display device layer EDL may be disposed on the circuit layer CL and include light-emitting diodes ED1, ED2, ED3 and a pixel definition film PDL.

The light-emitting diodes ED1, ED2, ED3 may each include a first electrode EL1, a hole functional layer HFL, a light-emission layer EML1, EML2, EML3, an electron functional layer EFL, and a second electrode EL2.

The pixel definition film PDL may be disposed on the circuit layer CL to cover a region between first electrodes EL1 in a plan view. The pixel definition film PDL may be disposed to correspond to a non-light-emission region NPA. The pixel definition film PDL may serve to separate the light-emitting diodes ED1, ED2, ED3.

The pixel definition film PDL may include one or more organic insulating materials including, for example, polyimide, polyamide, acrylic resin, benzocyclobutene, and phenol resin.

The first electrode EL1 may be disposed on the circuit layer CL. The first electrode EL1 may be conductive and connected to a pixel transistor to be applied with an electrical signal.

The hole functional layer HFL may be disposed between the first electrode EL1 and the light-emission layer EML1, EML2, EML3. The electron functional layer EFL may be disposed between the second electrode EL2 and the light-emission layer EML1, EML2, EML3.

However, example embodiments are not limited thereto, and depending on polarities of the first electrode EL1 and the second electrode EL2, positions of the hole functional layer HFL and the electron functional layer EFL may be interchanged.

The hole functional layer HFL and the electron functional layer EFL may be provided as a common layer as illustrated. However, example embodiments are not limited thereto, and one or both of the hole functional layer HFL and the electron functional layer EFL may be patterned to be disposed only in an opening part OH defined in the pixel definition film PDL.

The light-emission layer EML1, EML2, EML3 may be disposed in the opening part OH defined in the pixel definition film PDL.

One or more of the light-emission layers EML1, EML2, EML3 may be configured to emit light in different wavelength regions. For example, the light-emission layer EML1 of the first light-emitting diode ED1 may be configured to emit red light, the light-emission layer EML2 of the second light-emitting diode ED2 may be configured to emit green light, and the light-emission layer EML3 of the third light-emitting diode ED3 may be configured to emit blue light. However, example embodiments are not limited thereto, and the light-emission layers EML1, EML2, EML3 of the first through the third light-emitting diodes ED1, ED2, ED3 may be configured to emit light in a same wavelength region, for example blue light.

The light-emission layer EML1, EML2, EML3 may be formed by a deposition apparatus 1000 according to some example embodiments of the present disclosure. However, example embodiments are not limited thereto, and the layers formed through a deposition process among other layers of the display panel DP may also be formed by a deposition apparatus 1000 according to some example embodiments of the present disclosure.

The second electrode EL2 may be disposed on the light-emission layer EML1, EML2, EML3. The second electrode EL2 may face the first electrode EL1. The second electrode EL2 may have an integral (or conformal) shape extending from the light-emission region PA1, PA2, PA3 to the non-light-emission region NPA. The second electrode EL2 may be a common electrode.

The encapsulation layer TFE may be disposed on the display device layer EDL and configured to protect the light-emitting diodes ED1, ED2, ED3 of the display device layer EDL from moisture, oxygen, and/or impurities. The encapsulation layer TFE may include a glass substrate or synthetic resin substrate. However, example embodiments are not limited thereto, and the encapsulation layer TFE may be or include a laminated structure of an inorganic layer, an organic layer, and an inorganic layer.

A display device, according to some example embodiments of the present disclosure, may be used in a variety of electronic devices.

An electronic device, according to some example embodiments of the present disclosure, may include the above-described display device and further include a module or device having an additional function other than the display device.

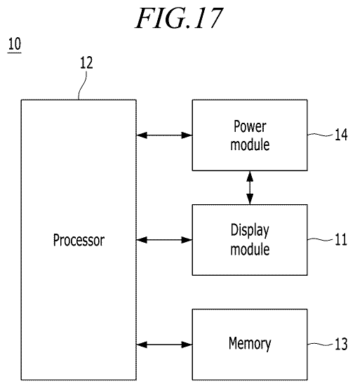

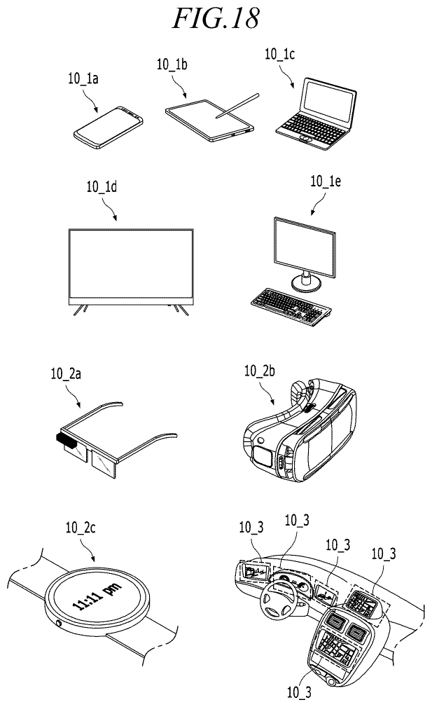

FIG. 17 is a block diagram of an electronic device according to some example embodiments of the present disclosure.

Referring to FIG. 17, an electronic device 10 according to some example embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operation of the processor 12 or the display module 11. When the processor 12 executes an application stored in the memory 13, an image data signal and/or an input control signal may be transmitted to the display module 11, and the display module 11 may be configured to process the received signal to output image information through the display screen.

The power module 14 may include a power supply module, such as a power adaptor and a battery device, and a power conversion module configured to convert power supplied from the power supply module to generate power used for operation of the electronic device 10.

One or more of the elements of the electronic device 10 may be included in a display device according to some example embodiments described above. In addition, some of individual modules functionally included in a single module may be incorporated to the display device while others are separately provided from the display device. For example, the display device may include a display module 11, and a processor 12, a memory 13, and a power module 14 may be provided in a form of a separate device, other than the display device, within the electronic device 10.

FIG. 18 are schematic diagrams of electronic devices according to some example embodiments.

Referring to FIG. 18, the different electronic devices 10 including a display device according to some example embodiments of the present disclosure may include an electronic device for displaying an image, such as a smartphone (10_1a), a tablet PC (10_1b), a laptop (10_1c), a TV (10_1d), and a desk monitor (10_1e), a wearable electronic device including a display module, such as a smart glasses (10_2a), a head-mounted display (10_2b), and a smartwatch (10_2c), and/or an electronic device for a vehicle including a display module 10_3, such as a dashboard of an automobile, a center fascia, CID (Center Information Display) disposed on a dashboard, and a room mirror display.

Example embodiments are not necessarily mutually exclusive. For example, some example embodiments may include one or more features described with reference to one or more figures, and may also include one or more other features described with reference to one or more other figures.

As described herein, any devices, systems, modules, portions, units, controllers, circuits, and/or portions thereof according to any of the example embodiments, and/or any portions thereof (including, without limitation, the display module 11, the processor 12, the memory 13, the power module 14, the smartphone (10_1a), the tablet PC (10_1b), the laptop (10_1c), the TV (10_1d), the desk monitor (10_1e), the smart glasses (10_2a), the head-mounted display (10_2b), the smartwatch (10_2c), the display module 10_3, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. An electrostatic mask chuck comprising:
a chuck body at least partially defining a plurality of opening parts and comprising a plurality of first bars, each of the plurality of first bars extending in a first direction and spaced apart from one another in a second direction, the second direction intersecting the first direction,
wherein, in a plan view, each first bar of the plurality of first bars separates a pair of neighboring opening parts of the plurality of opening parts in the second direction;
an electrode pattern on a first side of the chuck body; and
a dielectric layer on the first side of the chuck body and covering the electrode pattern,
wherein, in a plan view, the chuck body defines a peripheral region surrounding the plurality of opening parts, and
wherein the electrode pattern is on the peripheral region and the plurality of first bars.

2. The electrostatic mask chuck of claim 1,
wherein the electrode pattern extends in the first direction on each of the plurality of first bars and extends between the plurality of first bars and the peripheral region through both ends of each first bar.

3. The electrostatic mask chuck of claim 1,
wherein the electrode pattern is a straight line on each of the plurality of first bars.

4. The electrostatic mask chuck of claim 3,
wherein the electrode pattern comprises a first electrode pattern and a second electrode pattern, the first electrode pattern and the second electrode pattern each configured to receive power sources of different polarities,
wherein a pair of neighboring first bars of the plurality of first bars comprise a first sub bar and a second sub bar,
wherein the first electrode pattern is on the first sub bar, and
wherein the second electrode pattern is on the second sub bar.

5. The electrostatic mask chuck of claim 3,
wherein the plurality of first bars of the electrode pattern are configured to receive a power source having a same polarity.

6. The electrostatic mask chuck of claim 1,
wherein the electrode pattern comprises a first electrode pattern and a second electrode pattern, the first electrode pattern and the second electrode pattern configured to receive power sources of different polarities,
wherein a pair of neighboring first bars of the plurality of first bars comprise a first sub bar and a second sub bar,
wherein the first electrode pattern and the second electrode pattern are on the first sub bar, and
wherein the first electrode pattern and the second electrode pattern are on the second sub bar.

7. The electrostatic mask chuck of claim 1,
wherein, in a plan view, the dielectric layer comprises a first portion overlapping the peripheral region, and second portions overlapping the plurality of first bars, and
wherein the first portion comprises a first opposing surface facing the chuck body and a first chuck surface opposite to the first opposing surface, the second portions each comprise a second opposing surface facing the chuck body and a second chuck surface opposite to the second opposing surface, and the first chuck surface and the second chuck surface are in a same plane.

8. The electrostatic mask chuck of claim 1,
wherein the plurality of opening parts are symmetric with respect to each other about a first center line of the chuck body in a plan view, the first center line extending in the first direction.

9. The electrostatic mask chuck of claim 8,
wherein the plurality of opening parts each have a symmetrical shape about a second center line of the chuck body in a plan view, the second center line extending in the second direction.

10. The electrostatic mask chuck of claim 8,
wherein the plurality of opening parts comprise a first sub opening part and a second sub opening part neighboring the first sub opening part and farther away from the first center line than the first sub opening part, and
wherein a length of the second sub opening part in the first direction is less than a length of the first sub opening part in the first direction.

11. The electrostatic mask chuck of claim 10,
wherein the chuck body comprises a protruding part facing the second sub opening part in the first direction and the first sub opening part in the second direction, and
wherein at least a portion of the electrode pattern is on the protruding part.

12. The electrostatic mask chuck of claim 11,
wherein the electrode pattern comprises a first electrode pattern and a second electrode pattern the first electrode pattern and the second electrode pattern configured to receive different polarities,
wherein the first electrode pattern comprises first branch lines on the protruding part,
wherein the second electrode pattern comprises second branch lines on the protruding part,
wherein each first branch of the first branch lines extends in the second direction and the first branch lines face each other in the first direction, and
wherein each second branch line of the second branch lines extends in the second direction between a pair of neighboring first branch lines.

13. The electrostatic mask chuck of claim 1,
wherein the chuck body further comprises a plurality of second bars, each second bar of the plurality of second bars extending in the second direction and connecting a pair of neighboring first bars of the plurality of first bars.

14. The electrostatic mask chuck of claim 13,
wherein, in a plan view, the electrode pattern does not overlap the plurality of second bars.

15. The electrostatic mask chuck of claim 13,
wherein the dielectric layer comprises a first portion, second portions, and third portions, and, in a plan view, the first portion overlaps the peripheral region, the second portions overlap the plurality of first bars, and the third portions overlap the plurality of second bars, and
wherein the first portion comprises a first opposing surface facing the chuck body and a first chuck surface opposite to the first opposing surface, the second portions each comprise a second opposing surface facing the chuck body and a second chuck surface opposite to the second opposing surface, the third portions each comprise a third opposing surface facing the chuck body and a support surface opposite to the third opposing surface, and the first chuck surface, the second chuck surface and the support surface are in a same plane.

16. An electrostatic mask chuck comprising:
a chuck body at least partially defining a plurality of opening parts and comprising a plurality of first bars, each first bar of the plurality of first bars extending in a first direction and spaced apart from one another in a second direction, the second direction intersecting the first direction,
wherein, in a plan view, each first bar of the plurality of first bars separates a pair of neighboring opening parts of the plurality of opening parts in the second direction;
an electrode pattern on a first side of the chuck body; and
a dielectric layer on the first side of the chuck body and covering the electrode pattern,
wherein, in a plan view, the chuck body defines a peripheral region surrounding the plurality of opening parts,
wherein the dielectric layer comprises a first portion and second portions, and, in a plan view, the first portion overlaps the peripheral region and the second portions overlap the plurality of first bars, and
wherein the first portion comprises a first opposing surface facing the chuck body and a first chuck surface opposite to the first opposing surface, the second portions each comprise a second opposing surface facing the chuck body and a second chuck surface opposite to the second opposing surface, and the first chuck surface and the second chuck surface are in a same plane.

17. A deposition apparatus comprising:
a mask;
a deposition source configured to discharge a deposition material towards the mask; and
an electrostatic mask chuck between the mask and the deposition source, the mask attached to the electrostatic mask chuck,
wherein the electrostatic mask chuck comprises,
a chuck body at least partially defining a plurality of first opening parts and comprising a plurality of first bars, each of the plurality of first bars extending in a first direction and spaced apart from one another in a second direction intersecting the first direction,
wherein, in a plan view, each first bar of the plurality of first bars separates a pair of neighboring first opening parts of the plurality of first opening parts in the second direction;
an electrode pattern on a first side of the chuck body; and
a dielectric layer on the first side of the chuck body and covering the electrode pattern,
wherein, in a plan view, the chuck body defines a peripheral region surrounding the plurality of first opening parts, and
wherein the electrode pattern is on the peripheral region and the plurality of first bars.

18. The deposition apparatus of claim 17,
wherein the mask comprises a first surface facing the electrostatic mask chuck, and a second surface opposite to the first surface,
wherein the first surface defines second opening parts, and
wherein, in a plan view, the plurality of first opening parts cover the second opening parts.

19. The deposition apparatus of claim 18,
wherein, in a plan view, the peripheral region and the plurality of first bars do not overlap the second opening parts.

20. The deposition apparatus of claim 18,
wherein the mask comprises silicon wafer and the silicon wafer defines the second opening parts.
